(19) United States
(12) Patent Application Publication
(10) Pub. No.: US 2025/0058560 A1
(43) Pub. Date: Feb. 20, 2025

(54) INKJET PRINTING SYSTEM

(71) Applicants: Samsung Display Co., LTD., Yongin-si (KR); Soonchunhyang University Industry Academy Cooperation Foundation, Asan-si (KR)

(72) Inventors: Junghan SEO, Yongin-si (KR); Kye Si KWON, Asan-si (KR); Woo Yong SUNG, Yongin-si (KR); Seung Yong SONG, Yongin-si (KR); Jeongyeop JO, Asan-si (KR); Jinsol LEE, Asan-si (KR)

(21) Appl. No.: 18/666,247

(22) Filed: May 16, 2024

(30) Foreign Application Priority Data
Aug. 18, 2023 (KR) 10-2023-0108319

(51) Int. Cl. B41J 2/045

(52) U.S. Cl. CPC B41J 2/04508; B41J 2/0451; B41J 2/04581

(57) ABSTRACT

An inkjet printing system includes: an inkjet head unit including a nozzle for discharging ink, a driving unit for generating and outputting a driving voltage for discharging the ink from the nozzle, a first impedance adjusting unit disposed between an input terminal of the inkjet head unit and an output terminal of the driving unit and including a diode, and a self-sensing circuit unit that is connected to the input terminal of the inkjet head unit and receives a self-sensing voltage from the nozzle to determine whether the nozzle is operating normally.

This application claims priority to Korean Patent Application No. 10-2023-0108319, filed on Aug. 18, 2023, and all the benefits accruing therefrom under 35 U.S.C. § 119, the content of which in its entirety is herein incorporated by reference.

### BACKGROUND

### 1. Field

The present disclosure relates to an inkjet printing system.

### 2. Description of the Related Art

There may be various methods of forming each layer in a display device such as a liquid crystal display device or an organic light emitting diode display device, a semiconductor, a printed circuit board, a solar cell, or a sensor.

One of them may form a layer by ejecting ink droplet, and such an inkjet technology is applied not only to printers but also to a wide range of applications.

As the range of applications of inkjet technology as a manufacturing process expands, securing the reliability of ink droplets through nozzles has emerged as a very important issue.

As a method used to check the operation state of the inkjet head unit and nozzle ejection failure, a method of directly checking ink droplets ejected from the nozzle through a camera was used.

The method of using a camera has the advantage of being able to accurately measure the behavior as well as the speed of ink ejection, but accurate alignment must be performed for each nozzle, and calculation speed due to mechanical movement and image processing by the number of nozzles etc. is a problem, so there is a limit to quickly detecting defective nozzles.

Specifically, the nozzle monitoring method of the inkjet printing system directly ejects ink, and determines whether the ink ejected from a small number of nozzles is defective through a separate vision system.

This method takes a very long time because a small number of nozzles must be visualized sequentially through mechanical alignment control, and since it is a direct ejection method, there is a disadvantage in that ink is excessively wasted.

In addition, since the state of the nozzle continuously changes over time, there is a problem in that the monitoring result and the actual defect may not coincide in many cases.

### SUMMARY

Embodiments are intended to provide an inkjet printing system capable of accurately performing nozzle self-sensing together with nozzle driving.

In addition, embodiments are intended to provide an inkjet printing system capable of accurately monitoring a plurality of nozzles while accurately driving them with a single driver.

An inkjet printing system according to an embodiment includes: an inkjet head unit including a nozzle for discharging ink, a driving unit for generating and outputting a driving voltage for discharging the ink from the nozzle, a first impedance adjusting unit disposed between an input terminal of the inkjet head unit and an output terminal of the driving unit and including a pair of diodes, and a self-sensing circuit unit that is connected to the input terminal of the inkjet head unit and receives a self-sensing voltage from the nozzle to determine whether the nozzle is operating normally.

The pair of diodes of the first impedance adjusting unit may include a forward diode and a reverse diode.

Each of the forward diode and the reverse diode may be one of a PN junction diode, a Schottky diode, and a Zener diode.

The driving driver unit may be provided in plurality, the nozzle may be provided in plurality, the inkjet head unit may be connected to one of the driving units and may include the plurality of nozzles, and the inkjet head unit may further include a plurality of switches connected to the plurality of nozzles, respectively.

The self-sensing circuit unit may include a differential amplifier receiving the self-sensing voltage from the input terminal of the inkjet head unit, and the differential amplifier may further receive a reference voltage and subtracts the reference voltage from the self-sensing voltage to obtain a final self-sensing voltage.

The reference voltage may be input from the output terminal of the driving unit.

The inkjet printing system may further include: a second impedance adjusting unit connected to the output terminal of the driving unit and an input terminal of the differential amplifier, and the reference voltage may be input to the differential amplifier via the output terminal of the driving unit and the second impedance adjusting unit.

The second impedance adjusting unit may include an equivalent impedance adjusting unit having a configuration corresponding to the pair of diodes of the first impedance adjusting unit.

The second impedance adjusting unit may further include an equivalent capacitor unit corresponding to the nozzle included in the inkjet head unit.

The inkjet printing system includes: another inkjet head unit located adjacent to the inkjet head unit, including multiple nozzles and multiple switches connected to the multiple nozzles, respectively, the reference voltage may be input from the input terminal of the another inkjet head unit, and the reference voltage may be delivered when all of the multiple switches included in the another inkjet head unit are open.

The self-sensing circuit unit may further include a signal processing unit, which improves a signal-to-noise ratio using a filter.

The self-sensing circuit unit may further include a data determination unit configured to determine a state of the nozzle using the final self-sensing voltage.

An inkjet printing system according to an embodiment includes: an inkjet head unit including a nozzle for discharging ink, a driving unit for generating and outputting a driving voltage for discharging the ink from the nozzle, a first impedance adjusting unit disposed between an input terminal of the inkjet head unit and an output terminal of the driving unit and including a forward diode, and a self-sensing circuit connected to the input terminal of the inkjet head unit and for receiving a self-sensing voltage from the nozzle to determine whether the nozzle is operating normally, where a forward direction of the forward diode is the output terminal of the driving unit to the inkjet head unit direction toward the input terminal.

The forward diode may be one of a PN junction diode, a Schottky diode, and a Zener diode.

The driving driver unit may be provided in plurality, the nozzle may be provided in plurality, the inkjet head unit may be connected to one of the driving units and may include the plurality of nozzles, and the inkjet head unit may further include a plurality of switches connected to the plurality of nozzles, respectively.

The self-sensing circuit may include: a differential amplifier for receiving the self-sensing voltage from the input terminal of the inkjet head; a signal processing unit, which improves a signal-to-noise ratio using a filter; and a data determination unit configured to determine a state of the nozzle, where the differential amplifier may further receive a reference voltage and generate a final self-sensing voltage by subtracting the reference voltage from the self-sensing voltage, and the state of the nozzle may be determined using self-sensing voltage.

The reference voltage may be input from the output terminal of the driving unit.

The inkjet printing system may further include: a second impedance adjusting unit is connected to the output terminal of the driving unit and an input terminal of the differential amplifier, where the second impedance adjusting unit may include an equivalent impedance adjusting unit having a configuration corresponding to the first impedance adjusting unit, and the reference voltage may be input to the differential amplifier through the output terminal of the driving unit and the second impedance adjusting unit.

The second impedance adjusting unit may further include an equivalent capacitor unit corresponding to the nozzle included in the inkjet head unit.

The inkjet printing system may include another inkjet head unit located adjacent to the inkjet head unit, including multiple nozzles and multiple switches connected to the multiple nozzles, respectively, the reference voltage can be input from the input terminal of the another inkjet head unit, and the reference voltage can be transmitted when all the multiple switches included in the another inkjet head unit are open.

According to embodiments, the driving and monitoring of the nozzle may be accurately performed using the impedance adjusting unit with respect to the driving voltage and the self-setting voltage having a trade-off relationship.

According to embodiments, manufacturing costs may be effectively reduced by connecting a plurality of nozzles to one driver and selectively driving and self-sensing each nozzle.

### BRIEF DESCRIPTION OF THE DRAWINGS

FIG. 1 is a schematic block diagram of an inkjet printing system according to an embodiment.

FIG. 2 is a diagram showing the structure of a part of an inkjet printing system according to an embodiment.

FIG. 3 is a graph showing current versus voltage characteristics of a PN junction diode.

FIG. 4 is a diagram showing the structure of a part of an inkjet printing system according to another embodiment.

FIG. 5 and FIG. 6 are diagrams illustrating characteristics of the inkjet printing system according to the embodiment of FIG. 4.

FIG. 7 and FIG. 8 are diagrams showing the structure of a part of an inkjet printing system according to another embodiment.

FIG. 9 is a graph showing current versus voltage characteristics of a Schottky diode.

FIG. 10 is a diagram showing characteristics of the inkjet printing system according to the embodiment of FIG. 8.

FIG. 11 is a diagram illustrating a structure of an impedance adjusting unit according to various embodiments.

FIG. 12 is a diagram showing the structure of an inkjet printing system according to an embodiment.

FIG. 13 is a diagram showing voltage waveforms in the embodiment of FIG. 12.

FIG. 14 is a diagram showing the structure of an inkjet printing system according to another embodiment.

FIG. 15 is a diagram showing voltage waveforms in the embodiment of FIG. 14.

FIG. 16 is a diagram showing the structure of an inkjet printing system according to another embodiment.

FIG. 17 is a diagram showing the structure of an inkjet printing system according to another embodiment.

FIG. 18 is a diagram showing voltage waveforms in the embodiment of FIG. 17.

FIG. 19 to FIG. 22 are diagrams showing the structure of an inkjet printing system according to another embodiment.

FIG. 23 is a diagram showing the structure of an inkjet printing system according to a comparative example.

FIG. 24 and FIG. 25 are diagrams showing voltage waveforms in the comparative example of FIG. 23.

### DETAILED DESCRIPTION

Hereinafter, with reference to the accompanying drawings, various embodiments will be described in detail so that those skilled in the art can easily carry out the present invention.

This invention may be embodied in many different forms and is not limited to the embodiments set forth herein.

In order to clearly describe the present invention, parts irrelevant to the description are omitted, and the same reference numerals are assigned to the same or similar components throughout the specification.

In addition, since the size and thickness of each component shown in the drawings are arbitrarily shown for convenience of explanation, the present invention is not necessarily limited to that which is shown.

In the drawings, the thickness is shown enlarged to clearly express the various layers and regions.

And in the drawings, for convenience of explanation, the thicknesses of some layers and regions are exaggerated.

Also, when a part such as a layer, film, region, plate, or component is said to be “above” or “on” another part, this is not only when it is “directly on” the other part, but also when there is another part in between.

In contrast, when an element is referred to as being “directly on” another element, there are no intervening elements present.

In addition, being “above” or “on” a reference part means being located above or below the reference part, and does not necessarily mean being located “above” or “on” it in the opposite direction of gravity.

In addition, throughout the specification, when a certain component is said to “include,” it means that it may further include other components without excluding other components unless otherwise stated.

In addition, throughout the specification, when reference is made to a “planar image,” it means when the target part is viewed from above, and when reference is made to a “cross-sectional image,” it means when a cross-section of the target part cut vertically is viewed from the side.

Also, throughout the specification, when “connected” is used, this does not mean only the case where two or more components are directly connected, but when two or more components are indirectly connected through another component or physically connected. In the case of being connected or electrically connected, as well as being referred to by different names depending on location or function, each part that is substantially integral may be connected to each other.

In addition, throughout the specification, when a portion such as a wiring, layer, film, region, plate, component, etc. “extends in a first direction or a second direction,” it means only a straight line extending in the corresponding direction. Instead, it is a structure that generally extends along the first direction or the second direction, and includes a structure that is bent at one part, has a zigzag structure, or extends while including a curved structure.

In addition, electronic devices (e.g., mobile phones, TVs, monitors, and notebook computers) including display devices and display panels described in the specification or display devices and display panels manufactured by the manufacturing method described in the specification are not excluded from the scope of the present specification.

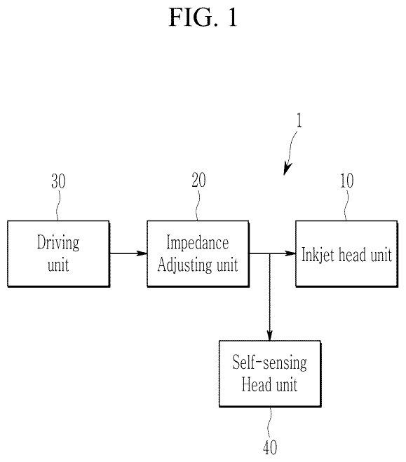

Hereinafter, a schematic structure of an inkjet printing system will be described with reference to FIG. 1.

FIG. 1 is a schematic block diagram of an inkjet printing system according to an embodiment.

An inkjet printing system 1 according to an embodiment may include an inkjet head unit 10, an impedance adjusting unit 20 (hereinafter referred to as a “first impedance adjusting unit”), a driving unit 30, and a self-sensing circuit unit 40.

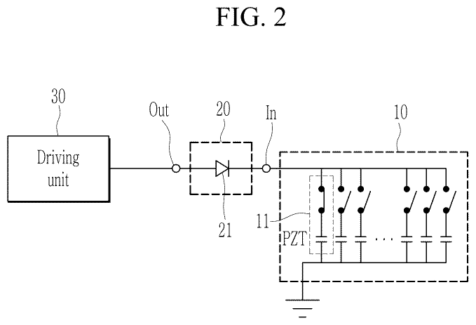

The inkjet head unit 10 is a main part of the inkjet printing device, and includes a nozzle (see 11 in FIG. 2) for discharging ink droplets, a piezo (see PZT in FIG. 2), and a switch.

When the driving voltage is transmitted to the piezo PZT in the inkjet head unit 10, a pressure wave of ink for ejection is generated in the head of the inkjet head unit 10 to eject ink droplets, and the residual pressure wave remains for a certain period of time after the ejection is finished. Through this, micro-deformation of the piezo PZT is generated and a vibration signal is generated.

Therefore, the piezo PZT is an actuator, but it can be used as a sensor at the same time.

The vibration signal of the pressure wave has information on the discharge state and can be measured by the self-sensing circuit unit 40 as a detection signal.

The driving unit 30 is a part that generates and outputs a driving voltage that causes the nozzles of the inkjet head unit 10 to discharge ink droplets, and is provided to the inkjet head unit 10 via the impedance adjusting unit 20.

Depending on the embodiment, the driving voltage output from the driving unit 30 may be directly transmitted to the self-sensing circuit unit 40, and the driving voltage transmitted in this way is used to extract a sensing signal from the self-sensing circuit unit 40, and it can be used to remove driving voltage.

The self-sensing circuit unit 40 monitors the nozzles of the inkjet head unit 10 using a self-sensing method, and amplification, differential, and filters are used in an analog circuit to easily determine whether a defect such as non-ejection occurs, it is a part constituting the circuit and can be connected to the input terminal of the inkjet head unit 10, receive the self-sensing voltage from the nozzle of the inkjet head unit 10, and process the signal to easily determine whether the nozzle is operating normally.

Specifically, the behavior of the pressure wave according to the driving voltage at the nozzle in the inkjet head unit 10 is indirectly measured by receiving the self-sensing voltage according to the amount of deformation of the piezo PZT, and in a normal state to a poor operating state, if the voltage changes, the behavior of the pressure wave of the ink changes, so whether the nozzle is defective or not can be confirmed from the change in the self-sensing voltage.

A high voltage of several tens of volts is used as a driving voltage for driving the nozzles in the inkjet head unit 10, and a relatively small voltage of 1V or less is generated as a self-sensing voltage for monitoring the nozzles.

Therefore, the size range of the sensing voltage is different from the driving voltage of the piezo PZT.

In addition, since the voltage generated in this way is formed in the form of a charge (in the form of electric charge) of the piezo PZT, it is immediately extinguished when connected to another voltage source.

Here, it is known that the piezo PZT is electrically identical to a capacitor.

Therefore, in order to measure the generated self-sensing voltage, these points may be considered, and it is difficult to obtain a signal by directly connecting the piezo PZT to the drive of the head in the inkjet head unit 10.

That is, from the point of view of ink ejection, when the output impedance of the driving unit 30 is small, the voltage is applied as it is without a change in the output driving voltage (distortion, signal size change), so that the ink ejection can proceed to an intended degree.

However, from the point of view of self-sensing, if the output impedance of the driving unit 30 is small, the voltage generated by the piezo PZT is all dissipated due to the voltage source of the driving unit 30, making it impossible to measure a desired signal.

Self-sensing is possible if the output impedance is increased by adding a resistor or capacitor element in the driving unit 30, but the driving voltage is greatly dropped or distorted, which affects the amount of ink discharged from the nozzle.

In order to eliminate the above trade-off relationship between the driving voltage and the self-sensing voltage, the impedance adjusting unit 20 is disposed between the driving unit 30 and the inkjet head unit 10 in the present embodiment.

The impedance adjusting unit 20 may include at least one diode, and may additionally include a device such as a resistor or a capacitor.

According to the impedance adjusting unit 20, the nozzle of the inkjet head unit 10 maximizes the sensing characteristics without changing the ejection characteristics so that the nozzles of the inkjet head unit 10 can operate by simultaneously optimizing the operation as an actuator and a sensor for discharging ink.

Specifically, the impedance adjusting unit 20 has a very low impedance to drive the nozzles of the inkjet head unit 10 and does not affect the driving voltage for ink ejection, but has a very high output impedance for self-sensing measurement, the charge and/or voltage generated by the piezo phenomenon in the nozzle can be effectively transferred to the self-sensing circuit unit 40 so that it can be measured.

The impedance adjusting unit 20 may be configured in various embodiments, and some of the various embodiments will be described through FIGS. 2 to 11 below.

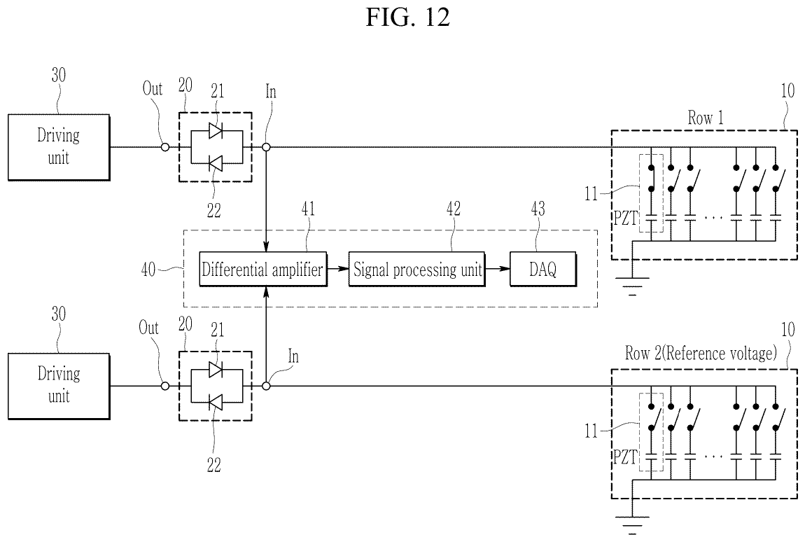

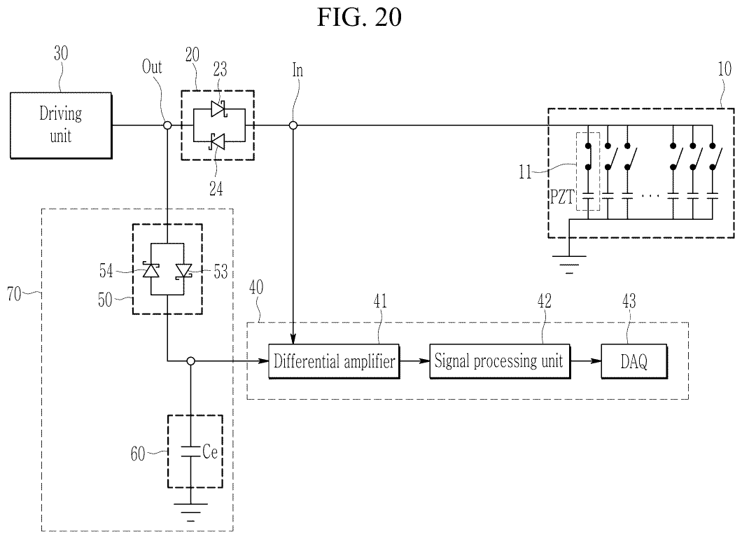

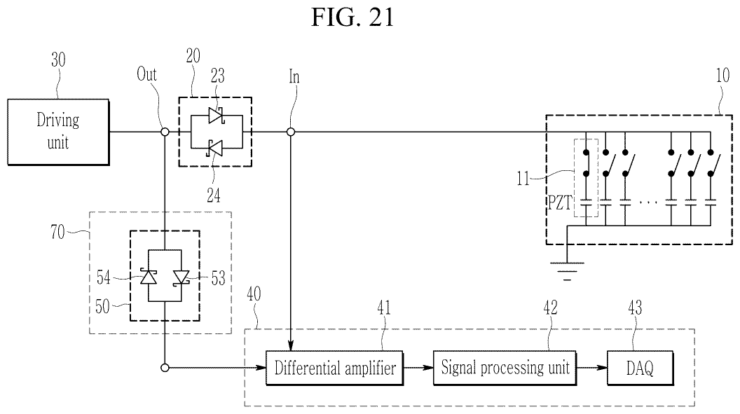

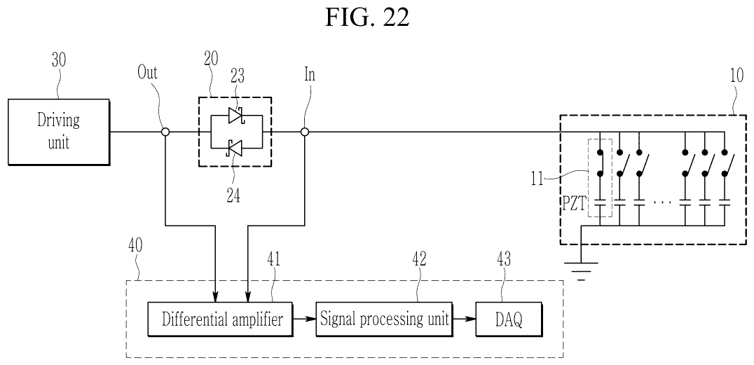

In FIGS. 2 to 11, the self-sensing circuit unit 40 is omitted, and various embodiments of the self-sensing circuit unit 40 will be described in detail in FIGS. 12 to 22.

FIG. 2 is a diagram showing the structure of a part of an inkjet printing system according to an embodiment.

In FIG. 2, the structure of the inkjet head unit 10 is shown in detail, and an embodiment including one diode 21 (hereinafter referred to as a “forward diode”) as the impedance adjusting unit 20 is shown.

First, the structure of the inkjet head unit 10 will be reviewed.

The inkjet head unit 10 includes a plurality of piezos PZT and a switch connected to each piezo PZT.

Here, the piezo PZT and the switch are bundled one by one to form one nozzle 11.

That is, a plurality of nozzles 11 are driven by one driving unit 30 and one impedance adjusting unit 20, and monitored through one self-sensing circuit unit 40, so that the inkjet printing system can be used.

As a result, manufacturing cost can be lowered, mass productivity can be greatly increased, and it can be used as a core technology for manufacturing displays and electronic devices.

One end of the nozzle 11 of FIG. 2 is connected to the input terminal In of the inkjet head unit 10, and the other end may be grounded or electrically connected to a portion corresponding to the ground.

Alternatively, when a voltage is applied to the other end, a difference between the input terminal In and the voltage applied to the other end may be an actual driving voltage.

In FIG. 2, the piezo PZT is replaced with a capacitor because the nozzle has characteristics similar to those of a capacitor on a circuit. However, unlike a general capacitor, the piezo PZT may have various characteristics of a piezoelectric element.

In FIG. 2, a switch included in one nozzle 11 is closed, and a switch included in the remaining nozzles 11 is open.

As a result, only the nozzle 11 whose switch is closed can eject ink or generate a pressure wave even if ink is not ejected, and through this, a self-sensing signal can be generated.

When multiple nozzles are connected to one driving unit 30, the state of the nozzles must be determined by applying a driving voltage to only one piezo PZT.

Therefore, even if a problem occurs in any nozzle, it is difficult to know.

Generally, in a multi-nozzle head, one drive operates 128 or 256 nozzles and has 8 or 4 independent driving units 30.

Therefore, each driving unit 30 can simultaneously scan one by one, and the scanning speed can be increased through such parallel scanning.

Therefore, depending on the embodiment, two or more nozzles 11 may be operated together.

The switch of each nozzle 11 may be controlled by a separate switch controller (not shown).

In an embodiment, in a process using an inkjet printing method, more than 100 multi-nozzle inkjet heads may be used to increase productivity.

The multi-nozzle inkjet head may include a plurality of nozzles 11 (more than 1,024), and may increase the productivity of the inkjet printing process by simultaneously using several heads and using tens of thousands of nozzles.

As the number of nozzles increases in such inkjet printing systems, the maintenance of the nozzles also becomes difficult, however, according to this embodiment, it is possible to self-sense the actual driven nozzle in real time, accurately monitor the operation of the piezo PZT, and ensure the stability of the inkjet printing system.

Here, the stability of the inkjet printing system can be determined through the accuracy, uniformity, and ejection of ink ejected from the piezo PZT, which is a very important factor affecting the yield and reliability of the inkjet printing process.

In an inkjet printing system according to an embodiment, each column may have a driving unit 30, and in an embodiment in which the inkjet printing system consists of 4 or 8 columns, the inkjet printing system includes 4 or 8 driving units 30.

Meanwhile, 128 or 256 nozzles 11 may be formed in each row.

When actual inkjet printing is performed, one drive simultaneously drives a plurality of nozzles so that inkjet printing can be performed at the same time.

In the embodiment of FIG. 2, the impedance adjusting unit 20 includes one forward diode 21 connected in a forward direction in view of the driving voltage output from the driving unit 30.

Hereinafter, the connection direction of the diode is a forward direction from the output terminal Out of the driving unit 30 to the input terminal In of the inkjet head unit 10, and is driven at the input terminal In of the inkjet head unit 10, and the direction toward the output terminal of the driving unit 30 is referred to as a reverse direction.

According to the forward diode 21 of the impedance adjusting unit 20 according to the embodiment of FIG. 2, when a driving voltage of high value (e.g., over 0.7V) is applied from the driving unit 30 to the inkjet head unit 10, the impedance is very small so that the driving voltage does not fluctuate. When the driving voltage is transmitted to the inkjet head unit 10 and the driving voltage is 0V or close to 0V, the impedance of the impedance adjusting unit 20 is very large, so that the self-sensing voltage is not applied to the impedance adjusting unit 20, and the self-sensing voltage is generated, the low voltage is amplified through the self-sensing circuit unit 40 without being affected by the voltage value (0V) of the driving unit 30 and is used to monitor the head in the inkjet head unit 10.

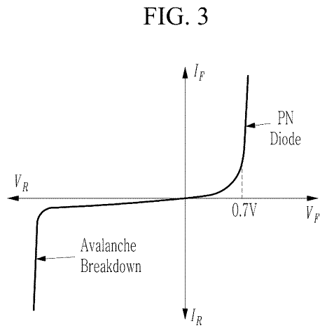

The forward diode 21 of the embodiment of FIG. 2 is a PN junction diode and may have characteristics similar to those of FIG. 3.

FIG. 3 is a graph showing current versus voltage characteristics of a PN junction diode.

FIG. 3 shows current characteristics according to voltage of a PN junction diode (PN diode).

In FIG. 3, VF means forward voltage, VR means reverse voltage, IF means forward current, and IR means reverse current.

Referring to FIG. 3, it can be seen that when a PN junction diode is used in a forward direction, a voltage drop of 0.7V may occur.

That is, up to 0.7V may be consumed to allow electrons and holes to meet and conduct current, after which it may have characteristics comparable to those of a conductor.

Therefore, even in the forward direction, if the voltage value is 0.7V or less, the impedance has a very large value and the voltage is not transferred to the other end.

In particular, since the voltage corresponding to self-sensing generated by the inkjet head unit 10 may have a low voltage of 0.7V or less, the signal of the residual pressure wave after the initial driving may be measured.

Therefore, for the self-sensing voltage generated from the piezo PZT of the inkjet head unit 10, the impedance value of the impedance adjusting unit 20 in FIG. 2 is very large, so the driving unit 30 does not act as a voltage source, and thus does not force the piezoelectric voltage to 0V.

In addition, since the high voltage for driving has little effect, the discharge is not affected.

On the other hand, referring to FIG. 3, when the voltage in the reverse direction is very high, insulator properties are broken and an avalanche breakdown may occur, but this voltage level is not generated from self-sensing.

FIG. 2 has an advantage in that the self-sensing voltage can be sensed without affecting the driving voltage by simply adding a forward diode 21.

In addition, in the embodiment of FIG. 2, when the driving voltage output from the driving unit 30 has a bipolar form having both positive and negative voltages, the forward diode 21 may operate as a reverse diode. Other embodiments may be used, such as the following.

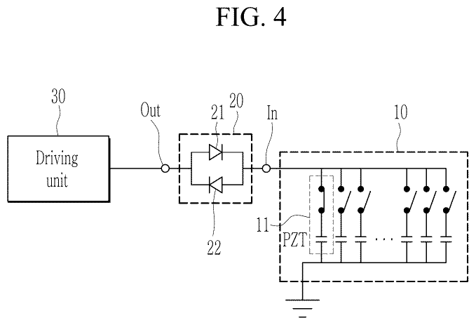

Hereinafter, the embodiment of FIG. 4 will be described.

FIG. 4 is a diagram showing the structure of a part of an inkjet printing system according to another embodiment.

In the embodiment of FIG. 4, the impedance adjusting unit 20 includes a pair of diodes composed of a forward diode 21 and a reverse diode 22.

When the self-sensing voltage has positive and negative voltages, and when the driving voltage is in bipolar (positive and negative voltage or alternating current) form, it is effective to connect the forward and reverse directions in parallel.

Therefore, in the embodiment of FIG. 4, the impedance adjusting unit 20 further includes a reverse diode 22 in addition to the embodiment of FIG. 2.

In the embodiment of FIG. 4, the reverse diode 22 has a large impedance when the driving voltage output from the driving 30 is transferred to the inkjet head unit 10, so it cannot pass through the reverse diode 22 or the forward diode 21 and is transferred to the inkjet head unit 10.

Meanwhile, the self-scan voltage generated by the inkjet head unit 10 may generally have a voltage of 1V or less, and when the input voltage becomes 0V after driving is finished, both the forward diode 21 and the reverse diode 22 (0V) of the driving voltage and the self-sensing voltage are cut off (open) and measured without being affected by the driving unit 30.

The measured self-sensing signal is transferred to the self-sensing circuit unit 40 for amplification and signal processing (analog filter, etc.).

On the other hand, when the piezo PZT of the inkjet head unit 10 accumulates charges due to characteristics similar to those of a capacitor, when the voltage exceeds a certain voltage (0.7V in FIG. 3), the accumulated charges are transferred to the driving unit 30 and removed. Thus, the problem of charge accumulation can be eliminated.

In addition, in the embodiment of FIG. 4, when the driving voltage output from the driving unit 30 has an alternating current form, due to the pair of diodes 21 and 22 formed in both directions, −1V (or −0.7V) in any case, and self-sensing voltage within the range of 1V (or 0.7V) can be efficiently measured.

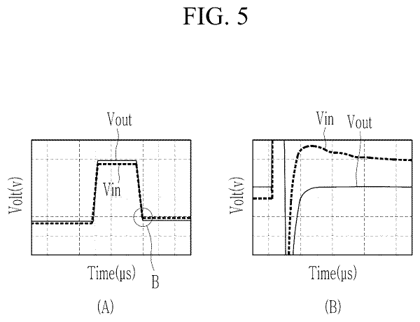

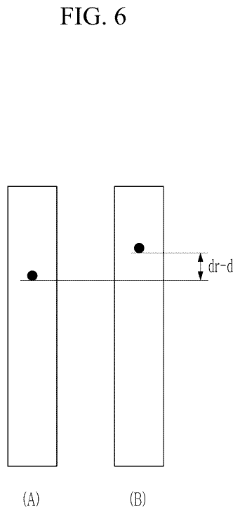

Hereinafter, characteristics of the embodiment of FIG. 4 will be reviewed through FIG. 5 and FIG. 6.

FIG. 5 and FIG. 6 are diagrams illustrating characteristics of the inkjet printing system according to the embodiment of FIG. 4.

The waveform of FIG. 5 will be looked at first.

In (A) of FIG. 5, the measured voltage is shown as the voltage Vin measured at the input terminal In of the inkjet head unit 10 in FIG. 4 and the voltage Vout measured at the output terminal Out of the driving unit 30.

Meanwhile, in (B) of FIG. 5, the voltage of part B of (A) of FIG. 5 is enlarged, and the voltage shown in (B) of FIG. 5 corresponds to one part of the self-sensing voltage.

In addition, the voltage measured in FIG. 5 is measured by connecting only one switch of one nozzle 11 in an embodiment in which the number of nozzles 11 connected to one driving unit 30 is 128 or 256.

Depending on the embodiment, one head may have 1,024 nozzles, 4 or 8 driving units for driving them, and 256 or 128 nozzles that can be simultaneously driven by each drive.

In (A) of FIG. 5, the voltage Vin measured at the input terminal In of the inkjet head unit 10 has a lower voltage than the voltage Vout measured at the output terminal Out of the driving unit 30, this means that the voltage drops while passing through the diode included in the impedance adjusting unit 20. When the diode is a PN junction diode, the corresponding lowered voltage value may be 0.7V with reference to FIG. 3.

Meanwhile, in (A) of FIG. 5, the high voltage may be 20V, which corresponds to the driving voltage.

In general, the driving voltage of the piezo PZT can be applied from several tens of volts to 100V or more.

The voltage in FIG. 5B is an example of the detected self-sensing voltage, and the peak-to-peak voltage may be 50 millivolts (mV), which is smaller than the voltage value of the driving voltage.

Since the self-sensing voltage generally has a magnitude lower than 0.7V, all measurements are possible without being affected by the driving voltage when the voltage at the driving unit 30 is 0V due to diode characteristics.

These signals are connected to the self-sensing circuit unit 40 for further amplification and signal processing.

If this signal has a sufficient signal compared to the noise, this sensing circuit unit can be omitted.

Therefore, when a high voltage is applied as a driving voltage to eject ink from the piezo PZT, the piezo PZT can be normally driven by passing through the forward diode 21, and the self-sensing voltage of 0.7V or less is the self-sensing circuit unit 40, it can be confirmed that it is effectively transmitted.

Meanwhile, FIG. 6 is a drawing of an ejection image of an ink droplet ejected from a piezo PZT photographed through a device called a drop watcher, and black dots shown in FIG. 6 indicate an ink droplet.

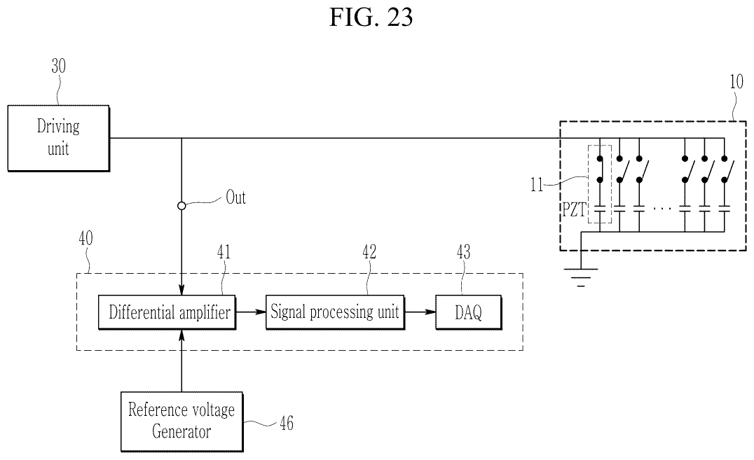

(A) of FIG. 6 is an ink droplet discharged in a comparative example not including the impedance adjusting unit 20 (refer to the comparative example in FIG. 23), and (B) of FIG. 6 is an ink droplet discharged in the embodiment of FIG. 4.

Referring to (B) of FIG. 6, it is shown that an ink droplet falls slowly by a distance dr-d due to a voltage drop of 0.7V generated by a diode included in the impedance adjusting unit 20.

Therefore, the ink ejection is substantially affected by the reduction of 0.7V, but when a plurality of piezos PZT are connected, the effect of the number of piezos PZT is insignificant, except that the ejection speed is slightly slowed overall. It does not affect the actual printing.

On the other hand, since the driving voltage can be applied by increasing the voltage by about 0.7V for the desired discharge speed, the discharge performance—for example, the effect of uniformity and/or crosstalk—is not substantially affected.

Therefore, in the embodiment of FIG. 2 or FIG. 4, since the driving voltage for ink ejection is as high as several tens of V (volts) or more and the self-sensing voltage is as small as 1V or less, the forward diode 21 of the impedance adjusting unit 20, a driving voltage of several tens of volts or more is applied as it is, with little impact.

On the other hand, the driving voltage applied after the ink is ejected becomes 0V, but at this time, since the impedance between the driving unit 30 and the inkjet head unit 10 is relatively large, the piezo PZT of the inkjet head unit 10 is measured as it is in the self-sensing circuit unit 40 without affecting the driving 30.

In the above, the diode of the impedance adjusting unit 20 used a PN junction diode.

However, since the PN junction diode has low frequency characteristics, when the discharge frequency is increased, the discharge characteristics may be changed.

In the case where discharge characteristics are affected due to such a disadvantage, other types of diodes may be used.

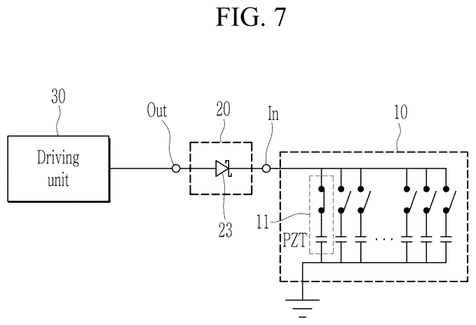

Hereinafter, an embodiment using a Schottky diode will be described through FIG. 7 to FIG. 10.

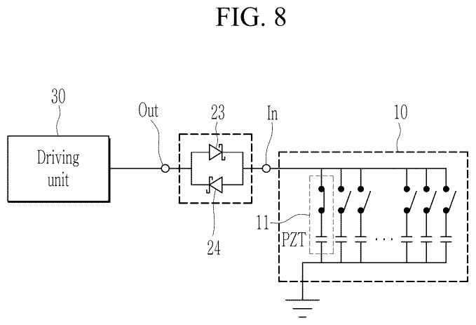

FIG. 7 and FIG. 8 are diagrams showing the structure of a part of an inkjet printing system according to another embodiment.

A Schottky diode is a diode that uses a phenomenon in which a large number of electrons move by a barrier between a metal and a semiconductor, and can also be called a Schottky barrier diode.

The embodiment of FIG. 7 is an embodiment in which a forward Schottky diode 23 is used instead of the forward diode 21 of the impedance adjusting unit 20 in the embodiment of FIG. 2.

The embodiment of FIG. 8 uses a forward Schottky diode 23 instead of the forward diode 21 of the impedance adjusting unit 20 in the embodiment of FIG. 4, and uses a reverse Schottky diode 24 instead of the reverse diode 22.

The embodiments of FIG. 7 and FIG. 8 have characteristics similar to those of the embodiments of FIG. 2 and FIG. 4, but may have improved frequency characteristics and discharge characteristics different from the embodiments using a PN junction diode due to the use of a Schottky diode.

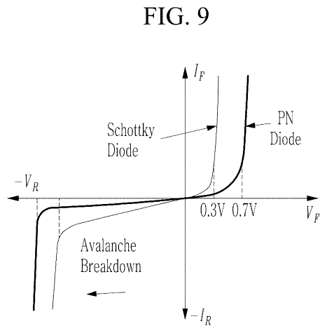

Hereinafter, the characteristics of the Schottky diode will be compared with the characteristics of the PN junction diode through FIG. 9.

FIG. 9 is a graph showing current versus voltage characteristics of a Schottky diode.

In FIG. 9, in addition to the characteristics of the PN junction diode of FIG. 3, the characteristics of a Schottky diode are additionally shown.

Referring to FIG. 9, the Schottky diode has a lower forward voltage drop in the I-V curve of the Schottky diode and the PN diode.

In the case of the Schottky diode, referring to FIG. 9, the forward voltage drop is 0.3V and the reverse recovery time is lowered to 1 microsecond (s) or less, so that the discharge characteristics of the piezo PZT are not affected even when operated at a high frequency.

On the other hand, referring to FIG. 9, it can be confirmed that the Schottky diode has a lower voltage level at which the avalanche breakdown occurs compared to the PN junction diode, but the voltage level at which the avalanche breakdown occurs is not used in the inkjet printing system.

Also, when a negative voltage is used, this problem can be overcome by parallel connection to use both directions of the diode.

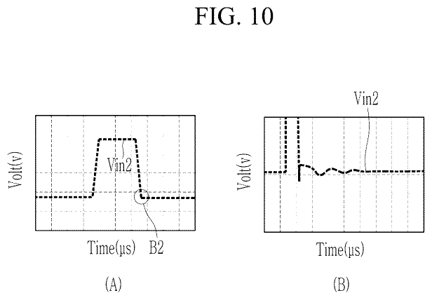

Hereinafter, voltage characteristics of the embodiment of FIG. 8 including Schottky diodes in both directions will be reviewed through FIG. 10.

FIG. 10 is a diagram showing characteristics of the inkjet printing system according to the embodiment of FIG. 8.

In (A) of FIG. 10, the measured voltage is the voltage Vin2 measured at the input terminal In of the inkjet head unit 10, and in (B) of FIG. 10, the voltage at B2 of (A) of FIG. 10 is enlarged, and the voltage shown in (B) of FIG. 10 may correspond to a part of the self-sensing voltage.

The voltage measured in FIG. 10 was measured in the same way as in FIG. 5.

When a Schottky diode is used, improved sensing characteristics can be obtained due to fast frequency characteristics and improved characteristics.

When measuring the actual measured voltage as an example, improved results can be obtained, and the self-sensing voltage shown in (B) of FIG. 10 is a peak-to-peak voltage of 300 mV, which is a larger self-sensing voltage compared to the PN diode in FIG. 5.

However, when the Schottky diode is used, the voltage drop value is smaller than that of the PN junction diode, and the voltage value of the driving voltage is almost similar, so it can be confirmed that there is little difference in the operation of the piezo PZT.

Therefore, by using the Schottky diode, it is possible to form an inkjet printing system having improved characteristics such as improved frequency characteristics and reduced forward voltage drop.

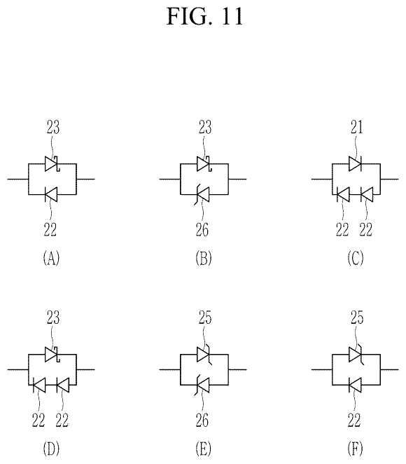

The impedance adjusting unit 20 included in the inkjet printing system 1 may have more diverse configurations, and a structure of some of them will be reviewed through FIG. 11.

FIG. 11 is a diagram illustrating a structure of an impedance adjusting unit according to various embodiments.

(A) to (F) of FIG. 11 show various embodiments of the impedance adjusting unit 20, and unlike the impedance adjusting unit 20 described above, PN junction diodes 21 and 22 and Schottky diodes 23, 24 or an embodiment including Zener diodes 25, 26 is shown.

The impedance adjusting unit 20 of the embodiment of (A) of FIG. 11 is composed of a Schottky diode 23 in a forward direction and a PN junction diode 22 in a reverse direction.

The impedance adjusting unit 20 of the embodiment of (B) of FIG. 11 is composed of a Schottky diode 23 in a forward direction and a Zener diode 26 in a reverse direction.

The impedance adjusting unit 20 of the embodiment of (C) of FIG. 11 is composed of a structure in which two forward-direction PN junction diodes 21 and two reverse-direction PN junction diodes 22 are connected in series.

The impedance adjusting unit 20 of the embodiment of (D) of FIG. 11 is composed of a structure in which two forward-direction Schottky diodes 23 and two reverse-direction PN junction diodes 22 are connected in series.

The impedance adjusting unit 20 of the embodiment of (E) of FIG. 11 is composed of a forward Zener diode 25 and a reverse Zener diode 26.

The impedance adjusting unit 20 of the embodiment of (F) of FIG. 11 is composed of a forward Zener diode 25 and a reverse PN junction diode 22.

Here, the Zener diodes 25 and 26 are a type of “semiconductor” diode, and are also referred to as constant voltage diodes.

The Zener diodes 25 and 26 have a PN junction structure similar to a PN junction diode, but have a characteristic of having a very low and constant breakdown voltage characteristic, so that current can flow when a voltage of a certain value or more is applied in the reverse direction.

Unlike the various embodiments of the impedance adjusting unit 20 shown in FIG. 11, the impedance adjusting unit 20 of another embodiment may be configured by changing or combining the types of diodes, and diodes may be additionally connected in parallel or in series.

In addition, according to embodiments, the impedance adjusting unit 20 may have a structure in which a resistor or a capacitor is additionally connected in series or parallel in addition to a diode.

In the above FIG. 2 to FIG. 11, various embodiments of the impedance adjusting unit 20 were mainly examined.

Hereinafter, various embodiments of the self-sensing circuit unit 40 will be described through FIG. 12 to FIG. 22.

Although the following FIG. 12 to FIG. 22 show that the impedance adjusting unit 20 includes a pair of diodes, it may include only one diode or various diodes of FIG. 11.

The embodiment of FIG. 12 will be looked at first.

FIG. 12 is a diagram showing the structure of an inkjet printing system according to an embodiment.

In the embodiment of FIG. 12, the embodiment having the impedance adjusting unit 20 as shown in FIG. 4 is mainly shown, and the embodiment in which the self-sensing circuit unit 40 uses two rows of voltage is shown.

Here, the inkjet head may have several columns.

Since there is a drive for each column, a sensing circuit can be configured for each column, but here, a circuit can be configured by pairing two columns.

The self-sensing circuit unit 40 extracts the final self-sensing voltage by removing the driving voltage component from the self-sensing voltage output from the inkjet head unit 10 through a differential amplifier and determines whether the piezo PZT is operating normally.

Specifically, the self-sensing circuit unit 40 can be quickly and accurately monitored using a self-sensing method.

Specifically, the self-sensing circuit unit 40 may use a piezo self-sensing method, and since the piezo self-sensing monitors through electrical signals, for example, an inkjet head unit (10) having 1,024 piezos PZT can determine the defective nozzles in a short time of several seconds or less.

This requires an algorithm for determining defective nozzles through a method of acquiring data by scanning each nozzle and an additional configuration of hardware.

In addition, a voltage lower than a driving voltage capable of ejecting ink droplets may be applied to the piezo PZT, thereby enabling monitoring without ejection.

Piezo self-sensing means that piezos PZT used as actuators are used as sensors at the same time, and in the inkjet printing system, a driving voltage is applied to the piezos PZT using a piezo actuator to eject ink.

After driving, a pressure wave of ink is generated in the piezo PZT and discharged.

Even after discharge, these pressure waves exist for a certain period of time, which causes deformation of the piezo PZT, and a voltage is generated in the piezo PZT in the form of a vibration signal which can be amplified by the self-sensing circuit unit 40 and processed by a differential circuit to obtain data.

Since the measured pressure wave signal shows a waveform that differs from the normal state according to the discharge state of the nozzle, it is possible to monitor the discharge state in real time.

The self-sensing circuit unit 40 can amplify the self-sensing voltage having a small voltage level while removing unnecessary driving voltage components from the voltage output from the piezo PZT.

Meanwhile, self-sensing voltage has a lot of information, so it can not only detect defective nozzles, but also detect the cause of the defect, it may be possible to use this for appropriate maintenance and the like.

In particular, it is possible to use various diagnoses and diagnosed results in combination with artificial intelligence.

To do this, signal sensitivity and the signal-to-noise ratio must be good.

Therefore, the self-sensing circuit unit 40 can process and use a self-sensing voltage with a high signal-to-noise ratio by using an analog filter such as a low-pass filter (“LPF”) or a high-pass filter (“HPF”) according to an embodiment.

The self-sensing circuit unit 40 according to the present embodiment may include a differential amplifier 41, a signal processing unit 42, and a DAQ (firmware for data acquisition and calculation; hereinafter referred to as a “data determination unit”).

The differential amplifier 41 is a part that subtracts two inputs and then amplifies the subtracted value and is included in the self-sensing voltage output from the piezo PZT based on the two input voltages, and can play a role in amplifying the final self-sensing voltage having a low voltage level after removing unnecessary driving voltage components during self-sensing.

The signal processing unit 42 may serve to increase the signal-to-noise ratio by using a filter for the amplified final self-sensing voltage, and an analog filter may be used.

In addition, the signal processing unit 42 may change the final self-sensing voltage through amplification or the like to match the voltage range in order to acquire data in the subsequent DAQ 43.

The DAQ 43 may acquire data to determine a state such as whether the corresponding piezo PZT of the inkjet head unit 10 is operating normally by using the final self-sensing voltage.

In the future, such data will be used by firmware or software to determine the state of the nozzle.

Meanwhile, in the self-sensing circuit unit 40, positions of the differential amplifier 41 and the signal processing unit 42 may be interchanged, depending on the embodiment, and the signal processing unit 42 or the DAQ 43 may be omitted.

Since the differential amplifier 41 has the purpose of performing an operation of subtracting two inputs in order to minimize the effect of the driving voltage when extracting the final self-sensing voltage, two input voltages are required.

One of the two must contain the self-sensing voltage, and the other must contain only the driving signal without the self-sensing voltage.

In FIG. 12, the differential amplifier 41 of the self-sensing circuit unit 40 receives a self-sensing signal from the input terminal In of two inkjet head units 10 included in two adjacent rows.

In FIG. 12, only the switch included in one nozzle 11 is closed in the inkjet head unit 10 included in the first row (Row 1), but in the inkjet head unit 10 included in the second row (Row 2), a switch included in all nozzles 11 has an open state.

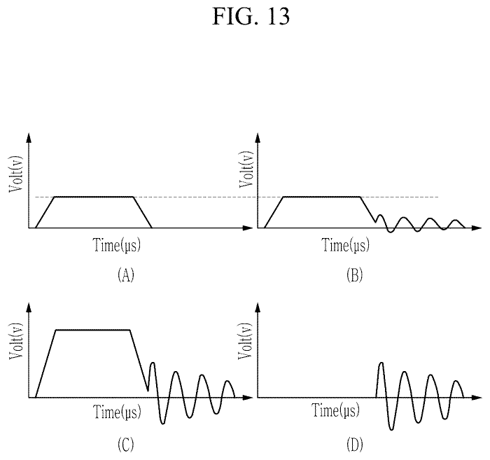

As a result, the self-sensing circuit unit 40 monitors the piezo PZT of the nozzle 11 having a closed switch among the inkjet head units 10 in the first row (Row 1), and the voltage input to the differential amplifier 41 received from the inkjet head unit 10 in the second row (Row 2) is not a self-sensing voltage, but a voltage that has passed through the impedance adjusting unit 20 in the second row output from the driving unit 30 that is, the reference voltage; see the voltage in (A) of FIG. 13.

FIG. 12 has a structure in which two adjacent rows are bundled into one self-sensing circuit unit 40.

In this way, when one nozzle is turned on from each of the two driving units 30 and the difference between the two signals is obtained, it is possible to extract the final self-sensing voltage while reducing the influence of the driving voltage.

Through this, the number of self-sensing circuit units 40 included in the inkjet printing system may be reduced, thereby reducing manufacturing cost.

Hereinafter, the step of extracting the final self-sensing voltage in the inkjet printing system of FIG. 12 will be described in detail through FIG. 13.

FIG. 13 is a diagram showing voltage waveforms in the embodiment of FIG. 12.

(A) of FIG. 13 shows that the reference voltage—that is, the voltage output from the driving unit 30—passes through the impedance adjusting unit 20, and (B) of FIG. 13 shows the measured self-sensing voltage. (C) of FIG. 13 shows the amplified self-sensing voltage, and (D) of FIG. 13 shows the amplified waveform of the final self-sensing voltage obtained by removing the driving voltage component as an output of the differential amplifier 41.

In the differential amplifier 41 of FIG. 12, the self-sensing voltage as shown in (B) of FIG. 13 is applied from the first row (Row 1), and the driving voltage output from the driving unit 30 is applied from the second row (Row 2). A voltage passed through the impedance adjusting unit 20—that is, a reference voltage as shown in (A) of FIG. 13—may be applied.

Here, the nozzle has several rows, and each row is not limited to a description corresponding to a drive method that drives independently or a method for a head having this structure.

Here, the reference voltage may correspond to a driving voltage component included in the self-sensing voltage.

That is, the voltage input from the differential amplifier 41 from the second row (Row 2) is the self-sensing voltage since the switches included in all nozzles 11 are open in the inkjet head unit 10 of the second row (Row 2), and the driving voltage output from the driving unit 30 may be a voltage that has passed through the impedance adjusting unit 20.

The differential amplifier 41 subtracts the voltage of (A) of FIG. 13 from the voltage of (B) of FIG. 13, amplifies it, and outputs the voltage shown in (D) of FIG. 13.

(C) of FIG. 13 is a direct amplification of the voltage of (B) of FIG. 13, and if the self-sensing voltage is directly amplified as in (C) of FIG. 13, the driving voltage component also increases, so it is impossible to obtain the output like (D) of FIG. 13 that is sought from the differential amplifier 41.

Therefore, in the embodiment of FIG. 12, the self-sensing circuit unit 40 removes the component of the reference voltage of (A) of FIG. 13—that is, the driving voltage—by directly inputting the voltage of (B) of FIG. 13 to the differential amplifier 41, and it is configured to amplify and generate an output as shown in (D) of FIG. 13.

The amplified final self-sensing voltage, which is the output voltage of the differential amplifier 41 as shown in (D) of FIG. 13, is input to the signal processing unit 42 and is changed to have a high signal-to-noise ratio through an analog filter, and after changing to the voltage range used in DAQ 43, it is input to the DAQ 43 and it is determined whether the corresponding piezo PZT is operating normally through computer or firmware calculation.

The inkjet printing system of the embodiment as shown in FIG. 12 has the advantage of reducing the number of self-sensing circuit units 40, but monitors only one piezo PZT of two columns, so relatively all piezos PZT There may be a disadvantage in that the time taken to conduct sequential monitoring increases.

On the other hand, unlike the embodiment of FIG. 12, in one of the two adjacent rows of the differential amplifier 41 of the self-sensing circuit unit 40, the self-sensing signal is received from the input terminal In of the inkjet head unit 10, and the other may have a modified structure in which a driving voltage is applied from the output terminal Out of the driving unit 30.

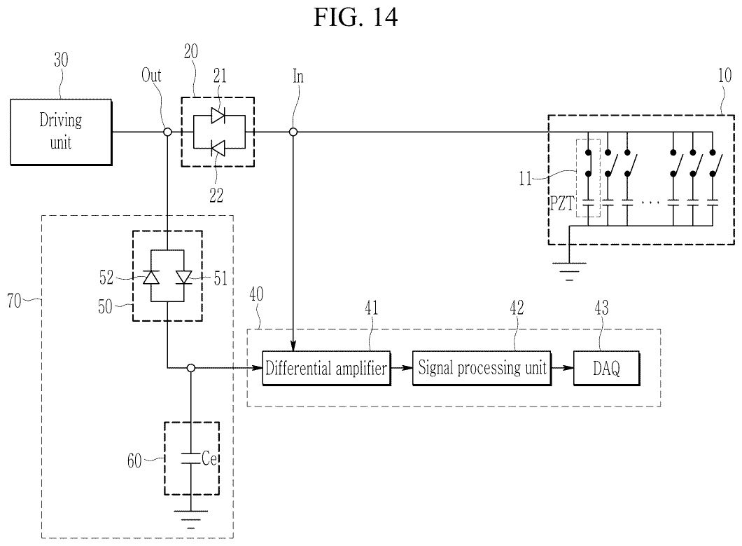

Hereinafter, the embodiment of FIG. 14 will be described.

FIG. 14 is a diagram showing the structure of an inkjet printing system according to another embodiment.

In FIG. 14, an example is formed where one self-sensing circuit unit 40 is formed in one row, and the reference voltage among the two voltages input into the differential amplifier 41 of the self-sensing circuit unit 40 could be the driving voltage at the output terminal Out of the driving unit 30 after passing through the additional impedance adjusting unit (70; also referred to as the “second impedance adjusting unit”).

Specifically, the self-sensing voltage input to the differential amplifier 41 is input from the input terminal In of the inkjet head unit 10, and the reference voltage is output from the output terminal Out of the driving unit 30. The driving voltage of the driving unit 30 is a voltage input to the differential amplifier 41 after passing through the additional impedance adjusting unit 70.

In the embodiment of FIG. 14, the driving voltage of the driving unit 30 is input to the impedance adjusting unit 20 and the additional impedance adjusting unit 70 from the output terminal Out of the driving unit 30.

In the embodiment of FIG. 14, the additional impedance adjusting unit 70 may include an equivalent impedance adjusting unit 50 and an equivalent capacitor unit 60.

Here, the equivalent impedance adjusting unit 50 may have a configuration corresponding to the impedance adjusting unit 20, and may have the same configuration as the impedance adjusting unit 20 depending on embodiments, and in the embodiment of FIG. 14, the equivalent impedance adjusting unit 50 includes bi-directional PN junction diodes 51 and 52 like the impedance adjusting unit 20.

The bi-directional PN junction diodes 21 and 22 included in the impedance adjusting unit 20 and the bi-directional PN junction diodes 51 and 52 included in the equivalent impedance adjusting unit 50 can each have the same voltage-current (VI) characteristics.

However, depending on embodiments, the equivalent impedance adjusting unit 50 may include only one diode, and in this case, may include only the forward diode 51.

Here, the forward diode may have the same VI characteristics as the forward diode 21 of the impedance adjusting unit 20.

Meanwhile, depending on embodiments, the diodes included in the impedance adjusting unit 20 and the equivalent impedance adjusting unit 50 may include different types of diodes.

Meanwhile, an equivalent capacitor unit 60 may be located at a rear end of the equivalent impedance adjusting unit 50.

The equivalent capacitor unit 60 may include a capacitor Ce having the same capacitance (electrostatic capacitance) of the piezo PZT in correspondence with one piezo PZT included in the inkjet head unit 10.

As shown in FIG. 14, when the additional impedance adjusting unit 70 is used, the differential amplifier 41 of the self-sensing circuit unit 40 cancels all electrical characteristics generated by driving the inkjet head unit 10 in the piezo PZT, so it is possible to effectively measure the final self-sensing voltage.

More specifically, since the piezo PZT of the inkjet head unit 10 has very similar electrical properties to a capacitor, charge accumulation by an applied voltage may occur as in a capacitor, and when the accumulated charge is discharged, an unwanted voltage is measured.

In order to eliminate such transient voltages, a reference voltage passing through an additional impedance adjusting unit 70 including an equivalent capacitor unit 60 and an equivalent impedance adjusting unit 50 is input into a differential amplifier 41, which perfectly offsets signals that are not related to the self-sensing voltage, making it possible to obtain the desired final self-sensing voltage.

In the embodiment as shown in FIG. 14, the additional impedance adjusting unit 70 is appropriately formed to cancel common mode noise, voltage drop due to diodes, and signal difference from diode frequency characteristics, etc. to obtain a more improved final self, so it is easy to extract the sensing voltage.

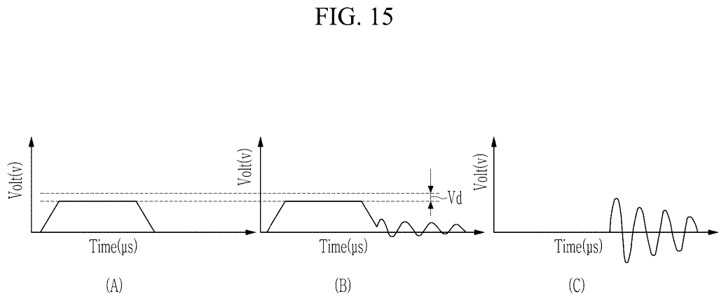

Hereinafter, the step of extracting the final self-sensing voltage in the inkjet printing system of FIG. 14 will be described in detail through FIG. 15.

FIG. 15 is a diagram showing voltage waveforms in the embodiment of FIG. 14.

(A) of FIG. 15 shows that the reference voltage—that is, the voltage output from the driving unit 30—passes through the additional impedance adjusting unit 70, and (B) of FIG. 15 shows the measured self-sensing voltage. (C) of FIG. 15 shows an amplified waveform of the final self-sensing voltage obtained by removing the driving voltage component as an output of the differential amplifier 41.

Meanwhile, the voltage drop value Vd shown by the dotted line in (A) of FIG. 15 and (B) of FIG. 15 indicates that the driving voltage output from the driving unit 30 passes through the impedance adjusting unit 20 and the equivalent impedance adjusting unit 50. It represents the voltage drop value that occurs while passing, and in the case of a PN junction diode, the voltage drop value Vd may be 0.7V.

When the voltage of (A) of FIG. 15 and the voltage of (B) of FIG. 15 are input to the differential amplifier 41, and the voltage of (A) of FIG. 15 is subtracted from the voltage of (B) of FIG. 15 and then amplified, the final self-sensing voltage of (C) of FIG. 15 of the same waveform is output.

The amplified final self-sensing voltage of (C) of FIG. 15 is input to the signal processing unit 42 and changed to have a high signal-to-noise ratio through an analog filter, after that, it is input to the DAQ 43 to obtain the final self-sensing voltage, and through calculation using this data, it is determined whether the corresponding piezo PZT is operating normally.

The embodiment of FIG. 14, unlike the embodiment of FIG. 12, has the advantage of reducing scanning time because the self-sensing circuit unit 40 is formed for each row, and each driver (from the nozzle of each row) scans simultaneously in parallel.

In addition, since the embodiment of FIG. 14 includes the equivalent impedance adjusting unit 50 and the equivalent capacitor unit 60 by using the additional impedance adjusting unit 70, it is possible to remove common phase noise and the like, so that the final self-sensing voltage may exhibit more accurate characteristics.

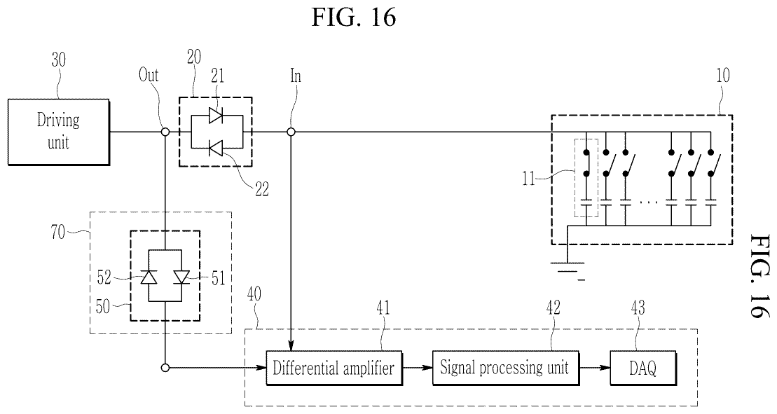

Meanwhile, depending on the embodiment, the structure of the additional impedance adjusting unit 70 may be different from that of FIG. 14, and a modified embodiment of FIG. 14 will be reviewed through FIG. 16.

FIG. 16 is a diagram showing the structure of an inkjet printing system according to another embodiment.

The embodiment of FIG. 16 is an embodiment in which the additional impedance adjusting unit 70 includes only the equivalent impedance adjusting unit 50, and does not include the equivalent capacitor unit 60 in the embodiment of FIG. 14.

In the embodiment of FIG. 16, since the additional impedance adjusting unit 70 includes the equivalent impedance adjusting unit 50, the reference voltage corresponding to the impedance adjusting unit 20 is transmitted to the differential amplifier 41, so that the final self-sensing is consistent with the embodiment of FIG. 14, and the sensing voltage may indicate accurate characteristics.

However, in the embodiment of FIG. 16, since the additional impedance adjusting unit 70 does not include the equivalent capacitor unit 60, it can be used while accepting noise caused by charges accumulated in the piezo PZT of the inkjet head unit 10.

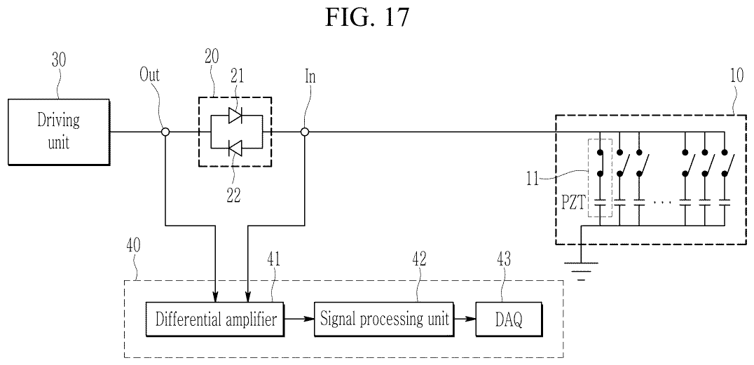

Hereinafter, the embodiment of FIG. 17 will be described.

FIG. 17 is a diagram showing the structure of an inkjet printing system according to another embodiment.

FIG. 17, unlike the embodiments of FIG. 14 or FIG. 16, does not include an additional impedance adjusting unit 70, and the reference voltage among the two voltages input into the differential amplifier 41 of the self-sensing circuit unit 40 is directly input from the output terminal Out of the driving unit 30, and it is an embodiment that uses the driving voltage of the driving unit 30 as the reference voltage itself.

The embodiment of FIG. 17 has an advantage in that the self-sensing circuit unit 40 is formed for each row and can be simply formed without additional configuration.

In the embodiment of FIG. 17, since the self-sensing voltage of the two voltages input to the differential amplifier 41 is the voltage that has passed through the impedance adjusting unit 20, it is the voltage at which the voltage drop is generated by the impedance adjusting unit 20, but is used as a reference voltage. Since the voltage is a driving voltage before passing through the impedance adjusting unit 20, it has a voltage value before a voltage drop occurs.

As a result, even if the two voltages are subtracted from the differential amplifier 41, the driving voltage component may not be completely removed.

However, even in the embodiment of FIG. 17, it can be confirmed whether the piezo PZT is operating normally through the final self-sensing voltage.

Unlike the embodiment of FIG. 12, the embodiment of FIG. 17 has the advantage of having a self-sensing circuit unit 40 formed in each row, so it takes less time to monitor all piezos PZT at once, and it also has the advantage of being able to be formed with a relatively simple structure.

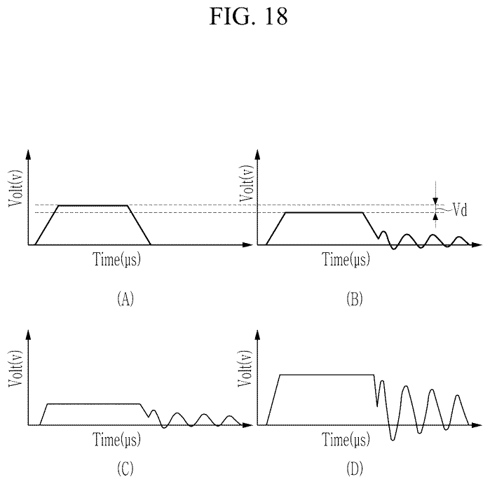

Hereinafter, the step of extracting the final self-sensing voltage in the inkjet printing system of FIG. 17 will be described in detail through FIG. 18.

FIG. 18 is a diagram showing voltage waveforms in the embodiment of FIG. 17.

(A) of FIG. 18 shows the reference voltage—that is, the driving voltage of the output terminal Out of the driving unit 30—and shows the voltage before passing through the impedance adjusting unit 20, FIG. 18 (B) represents the measured self-sensing voltage, (C) of FIG. 18 shows the voltage obtained by subtracting the voltage of (A) of FIG. 18 from the voltage of (B) of FIG. 18, and (D) of FIG. 18 shows the output of the differential amplifier 41. A waveform obtained by amplifying the voltage of (C) of FIG. 18 is shown as the final self-sensing voltage.

Meanwhile, the voltage drop value Vd shown by the dotted line in (A) of FIG. 18 and (B) of FIG. 18 is the voltage drop value generated when the driving voltage output from the driving unit 30 passes through the impedance adjusting unit 20. In the PN junction diode, the voltage drop value Vd may be 0.7V.

On the other hand, in the embodiment using the Schottky diode, the voltage drop value Vd may be lower, but compared to the voltage level of the self-sensing voltage, it may still have a large voltage value that cannot be ignored, so that the sensing signal is easy to measure.

In the amplified final self-sensing voltage of (D) of FIG. 18, unlike the final self-sensing voltage of the previous embodiment, the driving voltage component is not completely removed, but the self-sensing component located at the rear still exists, so the operating state of the corresponding piezo PZT can be checked.

At this time, among the results measured from the DAQ, if the data from the front part where some driving voltage exists is discarded (or is not used), or the front part of the data through the trigger delay is not measured when acquiring data, even if there is a certain degree of drive component, it may not significantly affect the actual sensing.

Therefore, the embodiments presented in this method are all possible methods for practical application.

The amplified final self-sensing voltage of (D) of FIG. 18 is input to the signal processing unit 42 and changed to have a high signal-to-noise ratio through an analog filter, it is then input to the DAQ 43, and the self-sensing component is extracted from the final self-sensing voltage to determine whether the corresponding piezo PZT is operating normally.

In addition, in the embodiment of FIG. 17, monitoring of the piezos PZT for each row is possible, so compared to the embodiment of FIG. 12, it takes relatively less time to monitor all the piezos PZT once.

However, referring to (D) of FIG. 18, since the driving voltage component may remain at a voltage value higher than the self-sensing component in the amplified final self-sensing voltage that is the output of the differential amplifier 41, the final self-sensing voltage is amplified, and there may be a limit to increasing the amplification rate.

In the embodiments of FIG. 12 to FIG. 18, a PN junction diode is used as a diode in the impedance adjusting units 20 and 70.

However, other types of diodes may be used depending on embodiments.

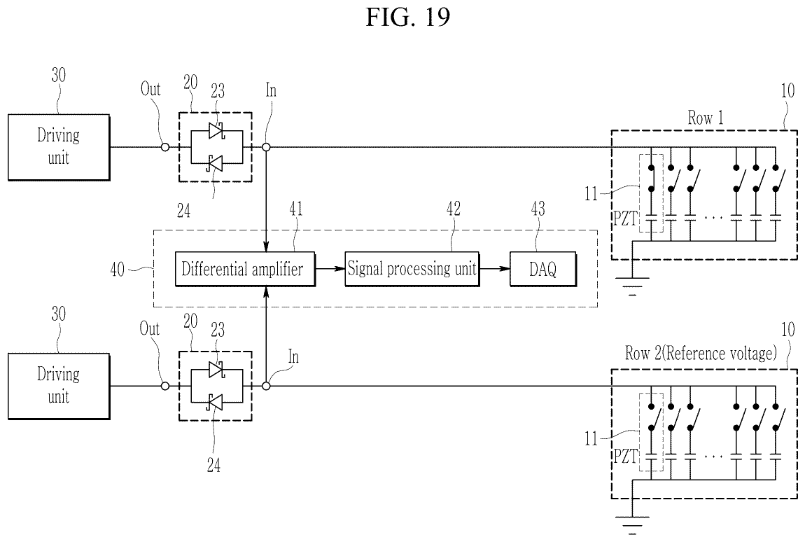

Some of these modified embodiments will be reviewed through FIG. 19 to FIG. 22.

FIG. 19 to FIG. 22 are diagrams showing the structure of an inkjet printing system according to another embodiment.

FIG. 19 to FIG. 22 are modified embodiments of FIGS. 12, 14, 16, and 17, respectively, and Schottky diodes 23, 24, 53, and 54 are used instead of PN junction diodes 21, 22, 51, and 52. An example of use is shown.

Since the Schottky diode is used, the voltage drop value of the voltage passing through the impedance adjusting unit 20 can be lower than that of the embodiment of the PN junction diode, and can be used even at a high frequency.

However, the overall characteristics may have the same effect as the corresponding embodiment.

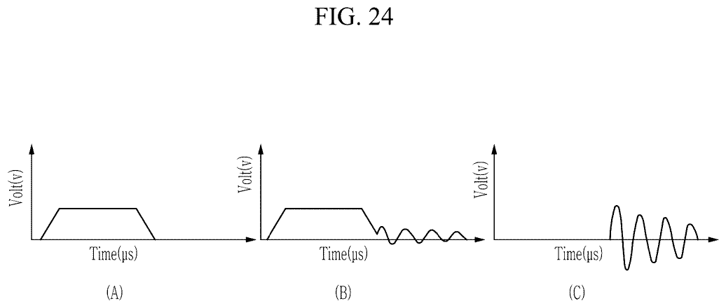

Hereinafter, the structure and voltage waveform of the inkjet printing system according to a comparative example not including the impedance adjusting unit 20 will be reviewed through FIG. 23 and FIG. 24 for comparison with the above-described embodiment.

First, the structure of the comparative example will be reviewed through FIG. 23.

FIG. 23 is a diagram showing the structure of an inkjet printing system according to a comparative example.

In the comparative example of FIG. 23, the impedance adjusting unit 20 is not included, so the output terminal Out of the driving unit 30 is the same as the input terminal of the inkjet head unit 10.

Therefore, the self-sensing circuit unit 40 receives the self-sensing voltage from the output terminal Out of the driving unit 30, and may further include a reference voltage generator 46 that additionally provides a reference voltage.

Here, the reference voltage may be the same as the voltage waveform output from the driving unit 30.

In the comparative example of FIG. 23, the final self-sensing voltage from which the driving component is removed can be generated by the differential amplifier 41 of the self-sensing circuit unit 40.

In other words, measurement is possible without an impedance converter (diode, etc.).

However, since the piezo PZT is used as both an actuator and a sensor, it is good if it satisfies both the performance of the actuator and the sensor, but the two are in a mutual trade-off relationship, in the comparative example of FIG. 23, there is a problem of improving the performance of one side and lowering the performance of the other side.

Specifically, since a high voltage is required to drive the piezo PZT, a driving unit 30 capable of outputting a high voltage driving voltage having a voltage level of several tens of volts or higher is required.

A driver with an amplifier is required.

In the comparative example of FIG. 23, since such a high-voltage driving voltage is directly applied to the piezo PZT, the output impedance of the driving unit 30 must be small to enable the driving voltage to be applied without change (distortion, signal size change) and the voltage is applied as it is, so that the piezo PZT is operating normally.

At this time, the voltage of the driving voltage may be slightly lowered.

On the other hand, if the output impedance of the driving unit 30 is small, the self-sensing voltage generated by the piezo PZT can be transferred to the driving unit 30 as well, so that the self-sensing voltage, which is a very low-level voltage, is self-sensing.

It is transmitted to the self-sensing circuit unit 40.

As such, when the self-sensing voltage is very small, a lot of amplification is performed in the self-sensing circuit unit 40, but since the amplification also increases noise, the signal-to-noise ratio of the self-sensing voltage becomes poor, resulting in poor detection.

On the other hand, if the output impedance of the driving unit 30 is high, the self-sensing voltage generated from the piezo PZT is not transmitted to the driving unit 30 but is well transmitted to the self-sensing circuit unit 40, so it can be well sensed, the driving voltage of the driving unit 30 is deformed and transmitted to the piezo PZT, and the piezo PZT may not operate normally.

As a result, in the comparative example shown in FIG. 23, it is difficult to accurately monitor the operation of the piezo PZT in a self-sensing method while normally driving the piezo PZT.

In addition, in the comparative example with the existing invention, a resistor and a capacitor can be additionally formed at the driver output so that the operation as a sensor and an actuator can be optimized at the same time, but in this case, the discharge capacity and sensor capacity of the piezo PZT are relatively reduced, there is a difference in that the self-sensing is not accurately performed without changing the discharge capacity because the driving voltage of the piezo PZT is not lowered as in the present embodiment.

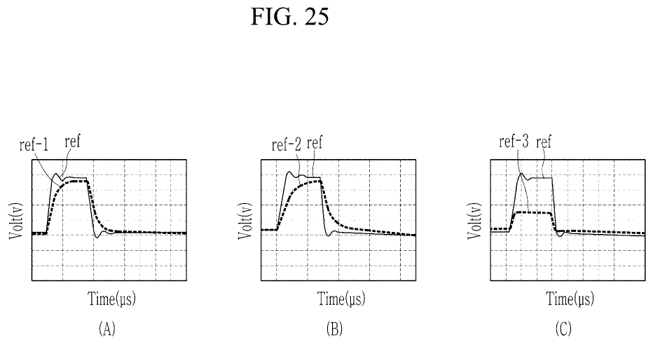

The characteristics of the comparative example of FIG. 23 will be examined in more detail through FIG. 24 and FIG. 25.

FIG. 24 and FIG. 25 are diagrams showing voltage waveforms in the comparative example of FIG. 23.

First, the voltage waveform of FIG. 24 will be examined.

(A) of FIG. 24 shows the reference voltage generated by the reference voltage generator 46, and the reference voltage may be the same as the driving voltage of the output terminal Out of the driving unit 30.

(B) of FIG. 24 shows the measured self-sensing voltage, and (C) of FIG. 24 shows a waveform obtained by amplifying the voltage obtained by subtracting the voltage of (A) of FIG. 24 from the voltage of (B) of FIG. 24.

In an ideal case, it seems possible to obtain a self-sensing voltage, but in reality, without impedance adjustment, the actual self-sensing signal is hardly visible or the entire sensing signal is forced into OV by the driver's OV, so it is very difficult to obtain a self-sensing signal as in FIG. 24.

As shown in (C) of FIG. 24, the final self-sensing voltage can be extracted without a component of the driving voltage, but as described above, when operating the piezo PZT with the driving voltage and obtaining the self-sensing voltage from the piezo PZT, the impedance of the output terminal Out of the driving unit 30 has a trade-off relationship with opposite characteristics, making it difficult to satisfy both characteristics and measuring the voltage at a level similar to noise to monitor the actual nozzle state.

According to the above embodiment, even if sensing is performed by inserting an impedance modifier (bi-directional diode), the change in the amount of ink discharged from the nozzle is minimized and hardly occurs.

This is because although a slight voltage drop may occur due to the impedance adjusting unit 20, the magnitude of the voltage is insignificant, and the discharge performance is not affected when the voltage is additionally increased and input.

Also, since the voltage waveform is not distorted, the effect of the driving voltage is minimized.

In addition, the self-sensing voltage generated by the nozzle due to the impedance adjusting unit 20 is transmitted to the self-sensing circuit unit 40 without affecting the driving voltage, so that detection performance is improved and monitoring can be performed accurately.

The impedance adjusting unit and the self-sensing circuit unit described in the above embodiments may be formed in the driving unit or in the inkjet head unit.

In an embodiment in which the impedance adjusting unit and the self-sensing circuit unit are formed in the driving unit, the driving unit itself may have a self-sensing function.

Meanwhile, in an embodiment in which the impedance adjusting unit and the self-sensing circuit unit are located within the inkjet head, the inkjet head may additionally include firmware capable of calculating and calculating additionally measured voltage.

Although the embodiments have been described in detail above, the scope of the present invention is not limited thereto, and various modifications and improvements of those skilled in the art using the basic concepts of the present invention defined in the following claims are also included in the scope of the present invention.

<Description of symbols>

| | |
|---|---|
| 1: | inkjet printing system |
| 10: | inkjet head unit |
| PZT: | piezo |
| 11: | nozzle |
| 20: | impedance adjusting unit |
| 30: | driving unit |
| 40: | self-sensing circuit unit |
| 41: | differential amplifier |
| 42: | signal processing unit |
| 43: | DAQ |
| 46: | reference voltage generator |
| 50: | equivalent impedance adjusting unit |
| 60: | equivalent capacitor unit |
| 70: | additional impedance adjusting unit |
| In: | input terminal of inkjet head unit |
| Out: | output terminal of driving unit |
| 21, 22, 23, 24, 25, | diode |
| 26, 51, 52, 53, 54: | |

What is claimed is:

1. An inkjet printing system, comprising:
an inkjet head unit including a nozzle for ejecting ink;
a driving unit configured to generate and output a driving voltage for discharging the ink from the nozzle;
a first impedance adjusting unit disposed between an input terminal of the inkjet head unit and an output terminal of the driving unit and including a pair of diodes; and
a self-sensing circuit connected to the input terminal of the inkjet head unit to receive a self-sensing voltage from the nozzle and determine whether the nozzle is normally operating.

2. The inkjet printing system of claim 1, wherein:
the pair of diodes of the first impedance adjusting unit include a forward diode and a reverse diode.

3. The inkjet printing system of claim 2, wherein:
each of the forward diode and the reverse diode is one of a PN junction diode, a Schottky diode, and a Zener diode.

4. The inkjet printing system of claim 2, wherein:
the driving driver unit is provided in plurality, and the nozzle is provided in plurality,
the inkjet head unit is connected to one of the driving units and includes the plurality of nozzles, and
the inkjet head unit further includes a plurality of switches connected to the plurality of nozzles, respectively.

5. The inkjet printing system of claim 2, wherein:
the self-sensing circuit unit includes a differential amplifier for receiving the self-sensing voltage from the input terminal of the inkjet head unit, and
the differential amplifier further receives a reference voltage and generates a final self-sensing voltage by subtracting the reference voltage from the self-sensing voltage.

6. The inkjet printing system of claim 5, wherein:
the reference voltage is input from the output terminal of the driving unit.

7. The inkjet printing system of claim 6, further comprising:
a second impedance adjusting unit connected to the output terminal of the driving unit and an input terminal of the differential amplifier; and
the reference voltage is input to the differential amplifier through the output terminal of the driving unit and the second impedance adjusting unit.

8. The inkjet printing system of claim 7, wherein:
the second impedance adjusting unit includes an equivalent impedance adjusting unit having a configuration corresponding to the pair of diodes of the first impedance adjusting unit.

9. The inkjet printing system of claim 8, wherein:
the second impedance adjusting unit further includes an equivalent capacitor unit corresponding to the nozzle included in the inkjet head unit.

10. The inkjet printing system of claim 5, further comprising:
another inkjet head unit positioned adjacent to the inkjet head unit and including a plurality of nozzles and a plurality of switches connected to the plurality of nozzles, respectively,
the reference voltage is input from an input terminal of the another inkjet head unit, and
the reference voltage is transmitted in a state in which all of the plurality of switches included in the another inkjet head unit are open.

11. The inkjet printing system of claim 5, wherein:
the self-sensing circuit unit further includes a signal processing unit, which uses a filter to improve a signal-to-noise ratio.

12. The inkjet printing system of claim 11, wherein:
the self-sensing circuit unit further includes a data determination unit configured to determine a state of the nozzle using the final self-sensing voltage.

13. An inkjet printing system, comprising:
an inkjet head unit including a nozzle for ejecting ink;
a driving unit configured to generate and output a driving voltage for discharging the ink from the nozzle;
a first impedance adjusting unit disposed between an input terminal of the inkjet head unit and an output terminal of the driving unit and including a forward diode; and
a self-sensing circuit unit connected to the input terminal of the inkjet head unit and configured to receive a self-sensing voltage from the nozzle to determine whether the nozzle is operating normally, and
a forward direction of the forward diode is a direction from the output terminal of the driving unit to the input terminal of the inkjet head unit.

14. The inkjet printing system of claim 13, wherein:
the forward diode is one of a PN junction diode, a Schottky diode, and a Zener diode, respectively.

15. The inkjet printing system of claim 13, wherein:
the driving driver unit is provided in plurality, and the nozzle is provided in plurality,
the inkjet head unit is connected to one of the driving units and includes the plurality of nozzles, and
the inkjet head unit further includes a plurality of switches connected to the plurality of nozzles, respectively.

16. The inkjet printing system of claim 13, wherein:
the self-sensing circuit unit comprises
a differential amplifier for receiving the self-sensing voltage from the input terminal of the inkjet head unit;
a signal processing unit, which improves a signal-to-noise ratio using a filter; and
a data determination unit for determining the state of the nozzle,
wherein the differential amplifier further receives a reference voltage and generates a final self-sensing voltage by subtracting the reference voltage from the self-sensing voltage, and
the data determination unit determines a state of the nozzle using the final self-sensing voltage.

17. The inkjet printing system of claim 16, wherein:
the reference voltage is input from the output terminal of the driving unit.

18. The inkjet printing system of claim 17, further comprising:
a second impedance adjusting unit connected to the output terminal of the driving unit and an input terminal of the differential amplifier;
wherein the second impedance adjusting unit includes an equivalent impedance adjusting unit having a configuration corresponding to the first impedance adjusting unit, and
the reference voltage is input to the differential amplifier through the output terminal of the driving unit and the second impedance adjusting unit.

19. The inkjet printing system of claim 18, wherein:
the second impedance adjusting unit further includes an equivalent capacitor unit corresponding to the nozzle included in the inkjet head unit.

20. The inkjet printing system of claim 16, further comprising:
another inkjet head unit positioned adjacent to the inkjet head unit and including a plurality of nozzles and a plurality of switches connected to the plurality of nozzles, respectively,
the reference voltage is input from an input terminal of the another inkjet head unit, and
the reference voltage is transmitted in a state in which all of the plurality of switches included in the another inkjet head unit are open.
